(19) United States
(12) Patent Application Publication
(10) Pub. No.: US 2009/0295690 A1
(43) Pub. Date: Dec. 3, 2009

(54) Electronic circuit and panel having the same

(75) Inventors: Yuuki Seo, Kanagawa (JP); Katsuhide Uchino, Kanagawa (JP); Hiroshi Sagawa, Kanagawa (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 12/385,497

(22) Filed: Apr. 9, 2009

(30) Foreign Application Priority Data
May 30, 2008 (JP) 2008-142438

(51) Int. Cl. G09G 3/30; H01L 33/00

(52) U.S. Cl. 345/76; 257/88; 257/E33.001

(57) ABSTRACT

Disclosed herein is an electronic circuit, including: a light emitting element, having diode characteristics, for emitting a light in accordance with a drive current; a sampling transistor for sampling a video signal; a driving transistor for supplying the drive current to the light emitting element; and a hold capacitor for holding therein a predetermined potential, the hold capacitor being connected to each of an anode side of the light emitting element, and a gate of the driving transistor; wherein a laminated portion of a first metallic layer serving as a gate of the sampling transistor, and a second metallic layer serving as a source of the sampling transistor is formed so as to have an area equal to or smaller than a predetermined area.

### BACKGROUND OF THE INVENTION

### 1. Field of the Invention

The present invention relates to an electronic circuit and a panel having the same, and more particularly to an electronic circuit which is capable reducing a dispersion of luminances in a panel, and the panel having the same.

### 2. Description of the Related Art

In recent years, a planar self-emission type panel using an organic Electro Luminescent (EL) device as a light emitting element (hereinafter referred to as “an EL panel”) has been actively developed. This EL panel, for example, is described in Japanese Patent Laid-Open Nos. 2003-255856, 2003-271095, 2004-133240, 2004-029791, and 2004-093682.

### SUMMARY OF THE INVENTION

In the existing EL panel, it is feared that there is a dispersion of luminances in pixels, and thus the dispersion of the luminances is seen as non-uniformity by an eye of a user. This is a problem involved in the existing EL panel.

The embodiment of present invention has been made in the light of such circumstances, and it is therefore desirable to provide an electronic circuit which is capable reducing a dispersion of luminances in a panel, and the panel having the same.

In order to attain the desire described above, according to an embodiment of the present invention, there is provided an electronic circuit including: a light emitting element, having diode characteristics, for emitting a light in accordance with a drive current; a sampling transistor for sampling a video signal; a driving transistor for supplying the drive current to the light emitting element; and a hold capacitor for holding therein a predetermined potential, the hold capacitor being connected to each of an anode side of the light emitting element, and a gate of the driving transistor; in which a laminated portion of a first metallic layer serving as a gate of the sampling transistor, and a second metallic layer serving as a source of the sampling transistor is formed so as to have an area equal to or smaller than a predetermined area.

According to another embodiment of the present invention, there is provided a panel including a pixel circuit having: a light emitting element, having diode characteristics, for emitting a light in accordance with a drive current; a sampling transistor for sampling a video signal; a driving transistor for supplying the drive current to the light emitting element; and a hold capacitor for holding therein a predetermined potential, the hold capacitor being connected to each of an anode side of the light emitting element, and a gate of the driving transistor; in which in the pixel circuit, a laminated portion of a first metallic layer serving as a gate of the sampling transistor, and a second metallic layer serving as a source of the sampling transistor is formed so as to have an area equal to or smaller than a predetermined area.

As set forth hereinabove, according to embodiments of the present invention, it is possible to suppress the dispersion of the luminances in the panel.

### BRIEF DESCRIPTION OF THE DRAWINGS

FIG. 1 is a block diagram showing a configuration of an existing EL panel as a basis;

FIG. 2 is a circuit diagram, partly in block, showing a configuration of an existing pixel in the existing EL panel shown in FIG. 1;

FIG. 3 is a timing chart explaining an operation of the existing pixel shown in FIG. 2;

FIG. 4 is a circuit diagram showing an operation state of the existing pixel for an emission time period;

FIG. 5 is a circuit diagram showing an operation state of the existing pixel at time t₁;

FIG. 6 is a circuit diagram showing an operation state of the existing pixel at time t₂;

FIG. 7 is a circuit diagram showing an operation state of the existing pixel at first time t₄ for a threshold correction time period;

FIG. 8 is a graph showing characteristics of a source voltage of a driving transistor in the existing pixel vs. time;

FIG. 9 is a circuit diagram showing an operation state of the existing pixel at time t₆;

FIG. 10 is a circuit diagram showing an operation state of the existing pixel at time t₇;

FIG. 11 is a graph showing characteristics of the source voltage of the driving transistor in the existing pixel vs. time with a mobility as a parameter;

FIG. 12 is a circuit diagram explaining the operation of the existing pixel shown in FIG. 2 in detail;

FIGS. 13A and 13B are respectively a top plan view showing an existing layout of a substrate for the existing pixel, and an equivalent circuit diagram of the existing pixel shown in FIG. 13A;

FIG. 14 is a timing chart, explaining an operation of the existing pixel, obtained by partially enlarging the timing chart shown in FIG. 3;

FIG. 15 is an equivalent circuit diagram of the existing pixel at a time point indicated by a circular frame shown in FIG. 14;

FIG. 16 is a top plan view explaining a difference in size of a parasitic capacitance parasitic on a writing transistor;

FIG. 17A is a top plan view showing an existing layout of the substrate for the existing pixel circuit;

FIG. 17B is a top plan view showing a layout of a substrate for a pixel circuit according to an embodiment of the present invention; and

FIG. 18 is a timing chart explaining an operation of the pixel circuit according to the embodiment of the present invention.

### DETAILED DESCRIPTION OF THE PREFERRED EMBODIMENTS

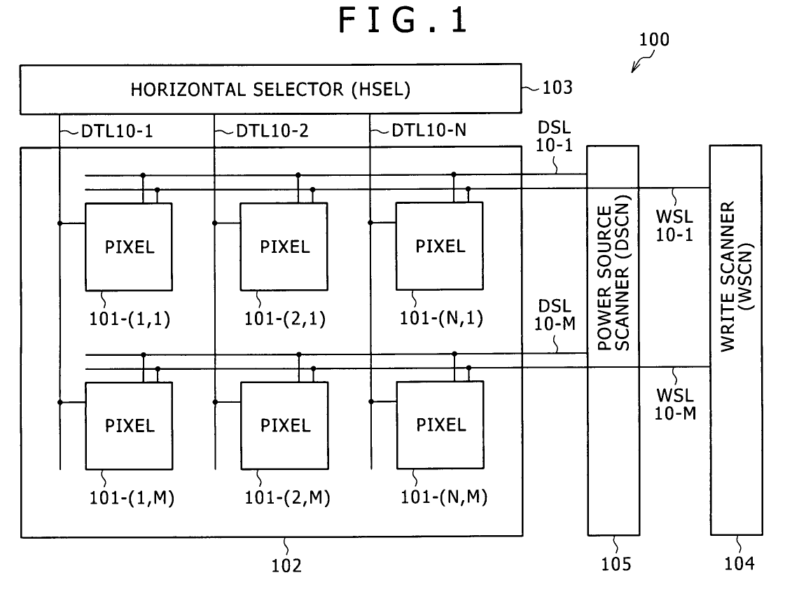

Firstly, in order to facilitate understanding of embodiments of the present invention and to make a background of the embodiments of the present invention clear, a configuration and an operation as a basis of a panel using an organic EL device (hereinafter referred to as “an EL panel”) will be described with reference to FIGS. 1 to 12.

FIG. 1 is a block diagram showing a configuration of the EL panel as the basis.

The EL panel 100 shown in FIG. 1 is composed of a pixel array portion 102, a horizontal selector HSEL 103, a write scanner WSCN 104, and a power source scanner DSCN 105. In this case, (N×M) pixels (pixel circuits) 101-(1, 1) to 101-(N, M) are disposed in a matrix in the pixel array portion 102. Also, the horizontal selector HSEL 103, the write scanner WSCN 104, and the power source scanner DSCN 105 drive the pixel array portion 102. Here, M and N are integral numbers which are set independently of each other.

In addition, the EL panel also has M scanning lines WSL10-1 to WSL10-M, M power source lines DSL10-1 to DSL10-M, and N video signal lines DTL10-1 to DTL10-N.

It is noted that when in the following description, there is no need for especially distinguishing the scanning lines WSL10-1 to WSL10-M, the video signal lines DTL10-1 to DTL10-N, the pixels 101-(1, 1) to 101-(N, M), or the power source lines DSL10-1 to DSL10-M from one another, they are simply referred to as the scanning lines WSL10, the video signal lines DTL10, the pixels 101, or the power source lines DSL10, respectively.

The pixels 101-(1, 1) to 101-(N, 1) belonging to the first row of the pixels 101-(1, 1) to 101-(N, M) are connected to the write scanner 104 and the power source scanner 105 through the scanning line WSL10-1 and the power source line DSL10-1, respectively. In addition, the pixels 101-(1, M) to 101-(N, M) belonging to the M-th row of the pixels 101-(1, 1) to 101-(N, M) are connected to the write scanner 104 and the power source scanner 105 through the scanning line WSL10-M and the power source line DSL10-M, respectively. This connection form in the row direction also applies to other pixels 101 disposed in the row direction of the pixels l01-(1, 1) to 101-(N, M).

In addition, the pixels 101-(1, 1) to 101-(1, M) belonging to the first column of the pixels 101-(1, 1) to 101-(N, M) are connected to the horizontal selector 103 through the video signal line DTL10-1. In addition, the pixels 101-(N, 1) to 101-(N, M) belonging to the N-th column of the pixels 101-(1, 1) to 101-(N, M) are connected to the horizontal selector 103 through the video signal line DTL10-N. This connection form in the column direction also applies to other pixels 101 disposed in the column direction of the pixels 101-(1, 1) to 101-(N, M).

The write scanner 104 successively supplies a control signal to the scanning lines WSL10-1 to WSL10-M with a horizontal period 1H, thereby scanning the pixels 101 in rows in a line-sequential manner. The power source scanner 105 supplies a power source voltage of a first potential Vcc which will be described later or a second potential Vss which will be described later to the power source lines DSL10-1 to DSL10-M in accordance with the line-sequential scanning. Also, the horizontal selector 103 switches a signal potential Vsig becoming a video signal, and a reference potential Vofs over to each other in each of the horizontal time periods 1H in accordance with the line-sequential scanning, thereby supplying the potential obtained through the switching to video signal lines DTL10-1 to DTL10-N wired in the column direction.

A panel module is configured by adding a driver Integrated Circuit (IC) composed of a source driver and a gate driver to the EL panel 100 configured as shown in FIG. 1. In addition, a display device is obtained by adding a power source circuit, an image Large Scale Integration (LSI), and the like to the panel module. The display device including the EL panel 100, for example, can be used as a display portion of a mobile phone, a digital still camera, a digital video camera, a television receiver, a printer or the like.

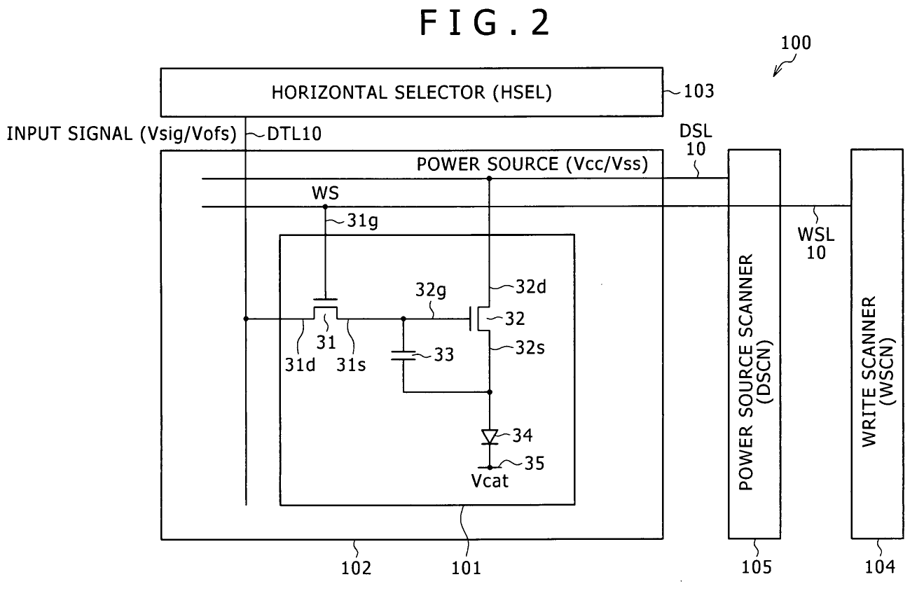

FIG. 2 is an enlarged diagram of one pixel 101 of the (N×M) pixels 101 included in the EL panel 100 shown in FIG. 1. That is to say, FIG. 2 is a circuit diagram, partly in block, showing a detailed configuration of each of the pixels 101 shown in FIG. 1.

It is noted that as apparent from FIG. 1, the scanning line WSL10, the video signal line DTL10, and the power source line DSL10 connected to the pixel 101 in FIG. 2 corresponds to the scanning line WSL10-(n, m), the video signal line DTL10-(n, m), and the power source line DSL10-(n, m) for the pixel 101-(n, m) (n=1, 2, . . . , N, and m=1, 2, . . . , M), respectively.

The pixel shown in FIG. 2 is composed of a writing transistor 31, a driving transistor 32, a storage capacitor 33, and a light emitting element 34. A gate 31g of the writing transistor 31 is connected to the scanning line WSL10 at a point WS. A drain 31d of the writing transistor 31 is connected to the video signal line DTL10. Also, a source 31s of the writing transistor 31 is connected to a gate 32g of the drive transistor 32.

One of a source 32s and a drain 32d of the drive transistor 32 is connected to an anode of the light emitting element 34, and the other thereof is connected to the power source line DSL10. The storage capacitor 33 is connected between the gate 32g of the driving transistor 32, and the anode of the light emitting element 34. In addition, a cathode of the light emitting element 34 is connected to a wiring 35 set at a predetermined potential Vcat.

In this example, each of the writing transistor 31 and the driving transistor 32 is configured in the form of an N-channel transistor and thus can be manufactured with amorphous silicon. Here, amorphous silicon can be more inexpensively made than low-temperature polysilicon can be made. Therefore, it is possible to greatly reduce a manufacture cost of the entire pixel circuit.

The light emitting element 34 emits a light at a gradation corresponding to a current value Ids supplied thereto. That is to say, the light emitting element 34 functions as an organic EL element as a current light emitting element.

In the pixel 101 configured in the manner as described above, when the writing transistor 31 is turned ON (conduction) in accordance with a control signal supplied thereto from the scanning line WSL10, the storage capacitor 33 accumulates and holds therein the electric charges supplied thereto from the horizontal selector 103 through the video signal line DTL10. That is to say, the predetermined voltage corresponding to the electric charges thus accumulated is held in the storage capacitor 33. The driving transistor 32 receives a current supplied thereto from the power source line DSL10 set at the first potential Vcc, and causes a drive current Ids corresponding to the signal potential Vsig held in the storage capacitor 33 to flow through the light emitting element 34. The predetermined drive current Ids is caused to flow through the light emitting element 34, so that the light emitting element 34 emits a light.

The pixel 101 has a threshold correcting function. The threshold correcting function means a function of causing the storage capacitor 33 to hold therein the voltage corresponding to a threshold voltage Vth of the drive transistor 32. The exercising of the threshold correcting function of the pixel 101 makes it possible to cancel an influence of the threshold voltage Vth of the drive transistor 32 causing the dispersion for each pixel of the EL panel 100.

In addition, the pixel 101 also has a mobility correcting function in addition to the threshold correcting function described above. The mobility correcting function means a function of adding the correction for a mobility μ of the driving transistor 32 to the signal potential Vsig when the signal potential Vsig is held in the storage capacitor 33.

Moreover, the pixel 101 has a bootstrap function as well. The bootstrap function means a function of causing a gate potential Vg to be cooperable with a change in source potential Vs of the driving transistor 32. The exercising of the bootstrap function of the pixel 101 makes it possible to hold a voltage developed across the gate 32g and the source 32s of the driving transistor 32 constant.

It is noted that the threshold correcting function, the mobility correcting function, and the bootstrap function will also be described later with reference to figures such as FIGS. 7, 11 and 12.

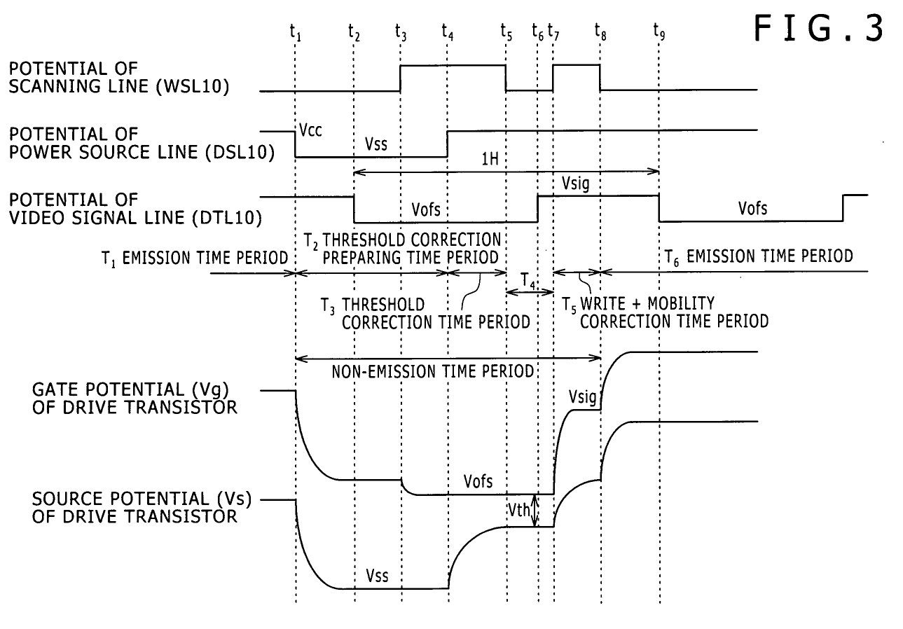

FIG. 3 is a timing chart explaining an operation of the pixel 101 shown in FIG. 2.

FIG. 3 shows changes in potentials of the scanning line WSL10, the power source line DSL10, and the video signal line DTL10 in the same time axis (in a transverse direction in the figure), and changes in gate potential Vg and source potential Vs of the driving transistor 32 corresponding to these changes.

In FIG. 3, a time period up to time t₁ is an emission time period T₁ for which the light emission for the previous horizontal time period 1H is carried out.

A time period from the time t₁ at end of the emission time period T₁ to time t₄ is a threshold correction preparing time period T₂ for which the gate potential Vg and the source potential Vs of the driving transistor 32 are initialized, thereby preparing for a threshold voltage correcting operation.

For the threshold correction preparing time period T₂, the power source scanner 105 switches the potential of the power source line DSL10 from the high potential Vcc over to the low potential Vss at the time t₁. Also, the horizontal selector 103 switches the potential of the video signal line DTL10 from the signal potential Vsig over to the reference potential Vofs at time t₂. Next, at time t₃, the write scanner 104 switches the potential of the scanning line WSL10 from the low potential over to the high potential, thereby turning ON the writing transistor 31. As a result, the gate potential Vg of the driving transistor 32 is reset at the reference potential Vofs, and the source potential Vs of the driving transistor 32 is reset at the low potential Vss of the video signal line DTL10.

A time period from time t₄ to time t₅ is a threshold correction time period T₃ for which the threshold voltage correcting operation is carried out. For the threshold correction time period T₃, at the time t₄, the power source scanner 105 switches the potential of the power source line DSL10 from the low potential Vss over to the high potential Vcc. As a result, the voltage corresponding to the threshold voltage Vth is written to the storage capacitor 33 connected between the gate 32g and the source 32s of the drive transistor 32.

For a write+mobility correction preparing time period T₄ from time t₅ to time t₇, the potential of the scanning line WSL10 is temporarily switched from the high potential over to the low potential. Also, at time t₆ just before the time t₇, the horizontal selector 103 switches the potential of the video signal line DTL10 from the reference potential Vofs over to the signal potential Vsig corresponding to the gradation.

Also, for a write+mobility correction time period T₅ from the time t₇ to time t₈, the operation for writing the video signal, and the mobility correcting operation are carried out. That is to say, for the write+mobility correction time period T₅ from the time t₇ to the time t₈, the potential of the scanning line WSL10 is set at the high potential. As a result, the voltage obtained by adding the signal potential Vsig of the video signal to the threshold voltage Vth is written to the storage capacitor 33, and a voltage ΔV_{μ} for mobility correction is subtracted from the voltage held in the storage capacitor 33.

At the time t₈ after end of the write+mobility correction time period T₅, the potential of the scanning line WSL10 is set at the low potential. Also, for an emission time period T₆ at end and after the time t₈, the light emitting element 34 emits a light with an emission luminance corresponding to the signal voltage Vsig. The emission luminance of the light emitting element 34 is free from an influence of dispersions of the threshold voltages Vth and the mobilities μ of the drive transistor 23 because the signal potential Vsig is adjusted with the voltage corresponding to the threshold voltages Vth, and the voltage ΔV_{μ} for mobility correction.

It is noted that the bootstrap operation is carried out at the first of the emission time period T₆, and as a result, each of the gate potential Vg and the source potential Vs of the driving transistor 32 rises while a gate-to-source voltage Vgs (=Vsig+Vth−Δ_{μ}) of the driving transistor 32 is held constant.

In addition, at time t₉ after a lapse of predetermined time from the time t₈, the potential of the video signal line DTL10 is caused to drop from the signal potential Vsig to the reference potential Vofs. In FIG. 3, a time period from the time t₂ to the time t₉ corresponds to the horizontal time period 1H.

In the manner as described above, in the EL panel 100 having the pixel 101 thus configured, it is possible to cause the light emitting element 34 to emit a light without coming under the influence of the dispersions of the threshold voltages Vth and the mobilities μ of the driving transistors 32.

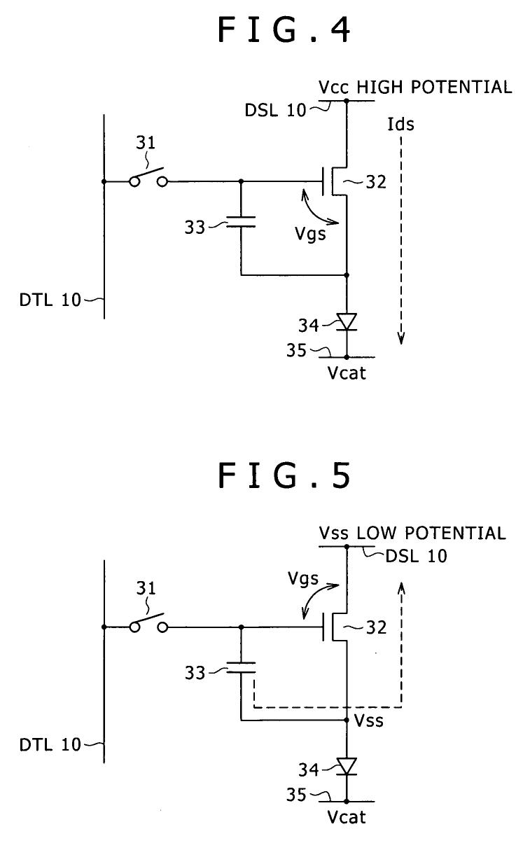

The operation of the pixel 101 will now be described in more detail with reference to FIGS. 4 to 12.

FIG. 4 shows the operation state of the pixel 101 for the emission time period T₁.

For the emission time period T₁, the writing transistor 31 is held in an OFF state (the potential of the scanning line WSL10 is held at the low potential), and the potential of the power source line DSL10 is held at the high potential Vcc. Thus, the driving transistor 32 supplies a drive current Ids to the light emitting element 34. At this time, since the driving transistor 32 is set so as to be operated in a saturated region, the drive current Ids caused to flow through the light emitting element 34 takes a value expressed by Expression (1) in accordance with the gate-to-source voltage Vgs of the driving transistor 32:

Ids=(½)·μ·(W/L)·Cox·(Vgs−Vth)² (1)

where μ is the mobility, W is a gate width of the driving transistor 32, L is a gate length of the driving transistor 32, Cox is a capacitance of a gate oxide film per unit area in the driving transistor 32, Vgs is the voltage developed across the gate 32g and the source 32s (gate-to-source voltage) of the driving transistor 32, and Vth is the threshold voltage of the driving transistor 32. It is noted that the saturated region means a state fulfilling a condition of (Vgs−Vth<Vds) (Vds is a voltage developed across the source 32s and the drain 32d of the driving transistor 32).

Also, at the first time t₁ of the threshold correction preparing time period T₂, as shown in FIG. 5, the power source scanner 105 switches the potential of the power source line DSL10 from the high potential Vcc (first potential) over to the low potential Vss (second potential). At this time, when the potential Vss of the power source line DSL10 is smaller than a sum of a threshold voltage Vthel and a cathode potential Vcat of the light emitting element 34 (when Vss<Vthel+Vcat), the light emitting element 34 makes emission quenching, and thus the side of the drive transistor 32 connected to the power source line DSL10 becomes the source 32s. In addition, the anode of the light emitting element 34 is charged at the low potential Vss with the electricity.

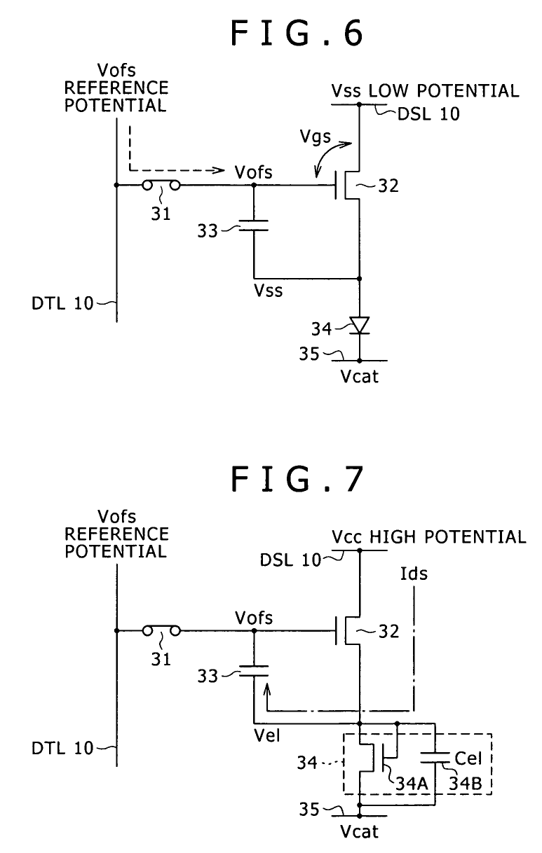

Next, as shown in FIG. 6, after the horizontal selector 103 switches the potential of the video signal line DTL10 from the signal potential Vsig over to the reference potential Vofs at the time t₂, the write scanner 104 switches the potential of the scanning line WSL10 from the low potential over to the high potential at the time t₃, thereby turning ON the write transistor 31. As a result, the gate potential Vg of the driving transistor 32 drops to the reference potential Vofs, so that the gate-to-source voltage Vgs of the driving transistor 32 takes a value of (Vofs−Vss). Here, the gate-to-source voltage Vgs of the driving transistor 32, that is, the voltage (Vofs−Vss) needs to be larger than the threshold voltage Vth (Vofs−Vss>Vth) from the necessity for carrying out the threshold correcting operation for the next threshold correction time period T₃. To put is the other way around, the reference potential Vofs and the low potential Vss are set so as to fulfill the condition of (Vofs−Vss>Vth).

Also, when as shown in FIG. 7, the power source scanner 105 switches the potential of the power source line DSL10 from the low potential Vss over to the high potential Vcc at the first time t₄ of the threshold correction time period T₃, the side of the driving transistor 32 connected to the anode of the light emitting element 34 becomes the source 32s. As a result, the current is caused to flow through a path indicated by a chain line shown in FIG. 7.

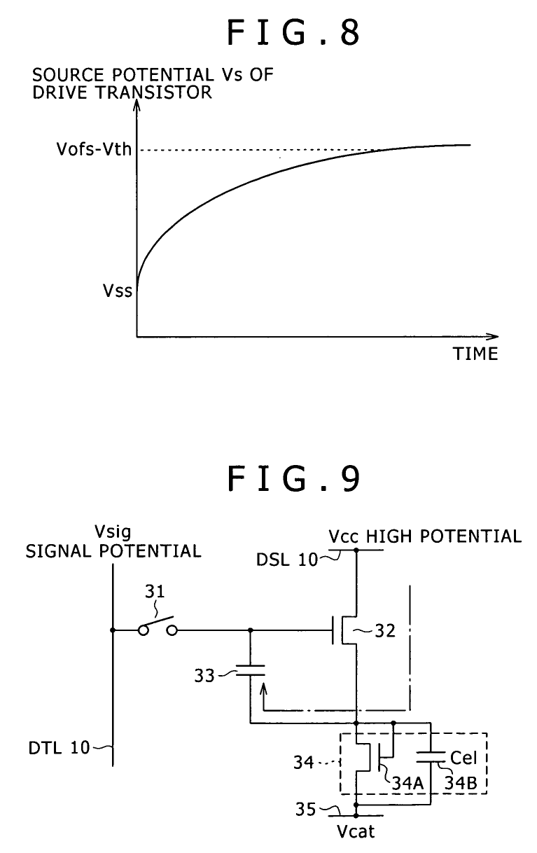

Here, the light emitting element 34 can be equivalenty expressed in the form of a parallel combination of a diode 34A and a storage capacitor 34B having a parasitic capacitance Cel parasitized thereon. Thus, the current caused to flow through the driving transistor 32 is used to charge each of the storage capacitors 33 and 34B with the electricity under the condition that a leakage current of the light emitting element 34 is considerably smaller than the current caused to flow through the drive transistor 32 (under the condition that the relationship of (Vel≦Vcat+Vthel) is fulfilled). The anode potential Vel of the light emitting element 34 (the source potential Vs of the driving transistor 32), as shown in FIG. 8, rises in accordance with the current caused to flow through the driving transistor 32. After a lapse of predetermined time, the gate-to-source voltage Vgs of the driving transistor 32 reaches the threshold voltage Vth of the driving transistor 32. In addition, the anode potential Vel of the light emitting element 34 at this time is given by (Vofs−Vth). Here, the anode potential Vel of the light emitting element 34 is equal to or smaller than a sum of the threshold voltage Vthel and the cathode potential Vcat of the light emitting element 34 (Vel=(Vofs−Vth)≦(Vcat+Vthel)).

After that, at the time t₅, as shown in FIG. 9, the potential of the scanning line WSL10 is switched from the high potential over to the low potential to turn OFF the write transistor 31, thereby completing the threshold correcting operation (the threshold correction time period T₃).

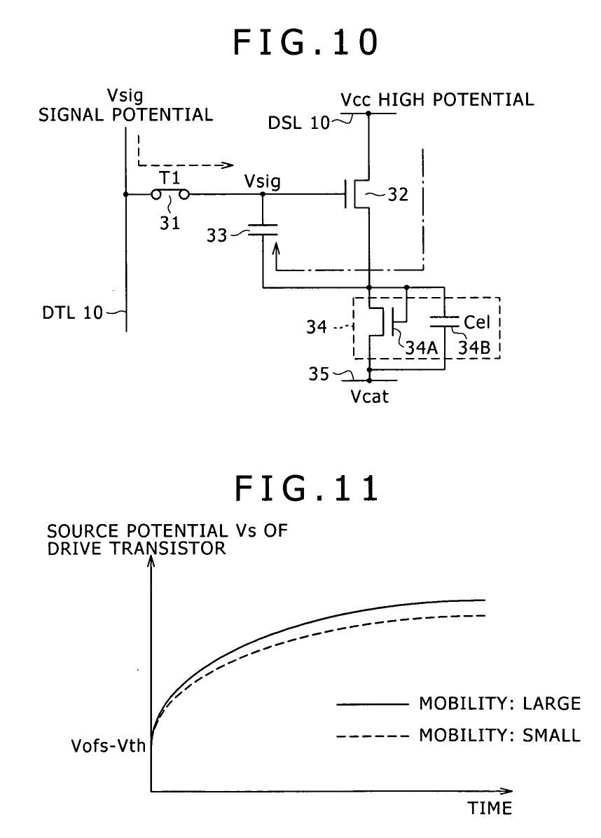

After at the time t₆ of the subsequent write+mobility correction preparing time period T₄, the horizontal selector 103 switches the potential of the video signal line DTL10 from the reference potential Vofs over to the signal potential Vsig corresponding to the gradation (refer to FIG. 9), the operation of the pixel 101 enters the write+mobility correction time period T₅. Thus, as shown in FIG. 10, the potential of the scanning line WSL10 is set at the high potential at the time t₇ to turn ON the writing transistor 31, so that the operation for writing the video signal, and the mobility correcting operation are carried out. The gate potential Vg of the driving transistor 32 is held at the signal potential Vsig because the writing transistor 31 is held in the ON state. However, the source potential Vs of the driving transistor 32 rises with time because the current from the power source line DSL10 is caused to flow through the writing transistor 31.

The threshold correcting operation for the driving transistor 32 has already been completed. Therefore, the term of (Vgs−Vth)² in the right-hand side member of Expression (1) is expressed by Expression (2):

$$\begin{matrix}{( Vgs - Vth )}^{2} = {\{ ( Vsig - ( Vofs - Vth ) ) - Vth \}}^{2} \\ = {( Vsig - Vofs )}^{2}\end{matrix} \qquad ( 2 )$$

As a result, since the influence of the term of the threshold voltage Vth is removed, the drive current Ids which the driving transistor 32 caused to flow reflects the mobility μ of the driving transistor 32. Specifically, as shown in FIG. 11, when the mobility μ is large, the drive current Ids from the driving transistor 32 becomes large, and thus the source potential Vs of the driving transistor 32 rapidly rises. On the other hand, when the mobility μ is small, the drive current Ids from the driving transistor 32 becomes small, and thus the source potential Vs of the driving transistor 32 slowly rises. In other words, at a time point after a lapse of given time, when the mobility μ is large, an amount, ΔV_{μ}, of source potential Vs risen of the driving transistor 32 (potential correction value) becomes large, while when the mobility μ is small, an amount, ΔV_{μ}, of source potential Vs risen of the driving transistor 32 (potential correction value) becomes small. As a result, the dispersion of the gate-to-source voltages Vgs of the driving transistors 32 in the pixels 101 becomes small because of the reflection of the mobility μ. Thus, the gate-to-source voltages Vgs of the pixels 101 after a lapse of the given time becomes the voltages for which the dispersion of the mobilities μ of the driving transistor 32 is perfectly corrected.

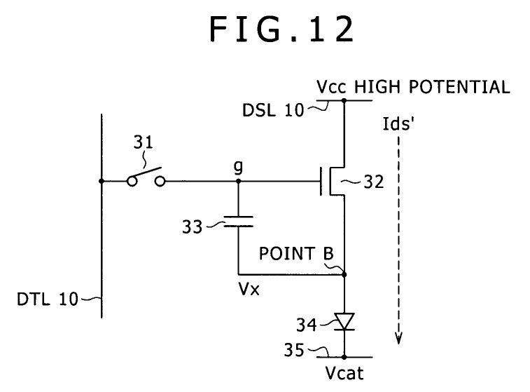

The potential of the scanning line WSL10 is set at the low potential at the time t₈, thereby turning OFF the writing transistor 31. As a result, the operation of the pixel 101 for the write+mobility correction time period T₅ is completed, and then enters the emission time period T₆ (refer to FIG. 12).

For the emission time period T₆, the gate-to-source voltage Vgs of the driving transistor 32 is held constant. Thus, the driving transistor 32 supplies the constant current Ids′ to the light emitting element 34, the anode potential Vel of the light emitting element 34 rises up to a voltage Vx with which the current, that is, the constant current Ids′ is caused to flow through the light emitting element 34. As a result, the light emitting element 34 emits a light. When the source potential Vs of the driving transistor 32 rises, the gate potential Vg of the driving transistor 32 also rises in conjunction with the rising of the source potential Vs of the driving transistor 32 based on the bootstrap function of the storage capacitor 33.

When the emission time period becomes long, a potential at a point B shown in FIG. 12 changes with time (deteriorates with time) in accordance with I-V characteristics of the light emitting element 34. However, the current caused to flow through the light emitting element 34 does not change because the gate-to-source voltage Vgs of the driving transistor 32 is held at a constant value. Therefore, even when the light emitting element 34 deteriorates with time in accordance with the I-V characteristics of the light emitting element 34, the constant current Ids′ is caused to continuously flow through the light emitting element 34. As a result, there is no change in luminance of the light emitting element 34.

As described above, in the EL panel 100, shown in FIG. 2, including the pixel 101, the dispersions of the threshold voltages Vth and the mobilities μ of the pixels 101 can be corrected based on the threshold correcting function and the mobility correcting function. In addition, the temporal change (deterioration) of the light emitting element 34 can also be corrected.

As a result, with the display device using the EL panel 100 shown in FIG. 2, the image quality of high grade can be obtained.

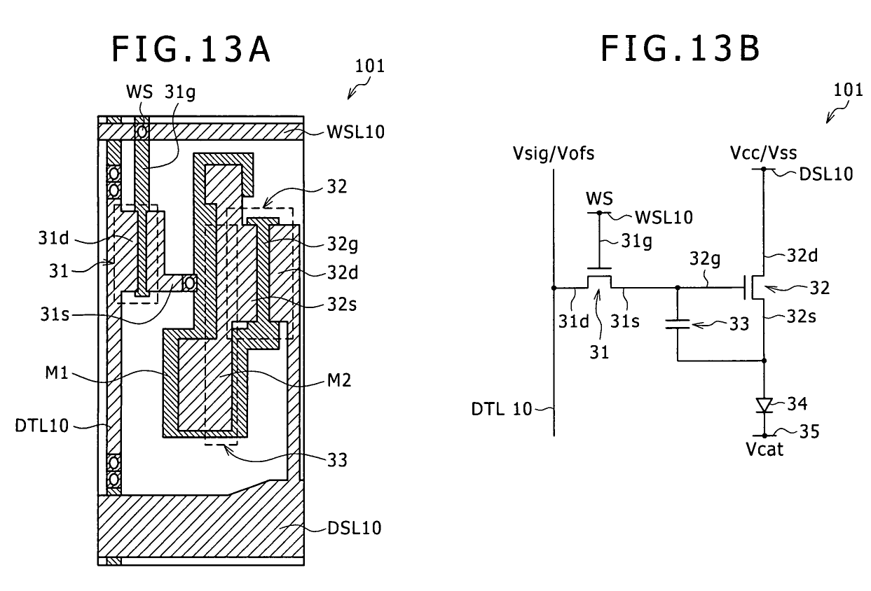

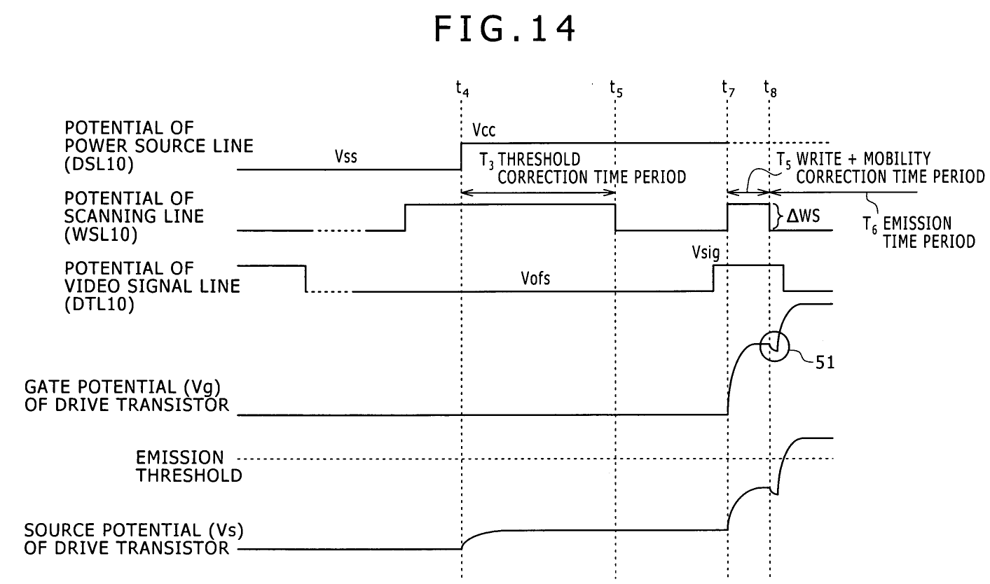

Here, the primary factor causing the problem, in the related art, which was described in the opening of the paragraph of “SUMMARY OF THE INVENTION” will be described with reference to FIGS. 13A and 13B to FIG. 16.

FIG. 13B shows an equivalent circuit of the pixel 101 shown in FIG. 2 again. FIG. 13A shows an existing layout of a substrate of the pixel 101 shown in FIG. 2.

At least a first metallic layer M1, and a second metallic layer M2 are laminated in the order from the lower side on the substrate shown in FIG. 13A by carrying out expose processing as one of manufacture process of the pixel 101. It is noted that in FIG. 13A, the first metallic layer M1 is shown by falling diagonal lines drawn from top left to bottom right, and the second metallic layer M2 is shown by rising diagonal lines drawn from bottom left to top right.

On the substrate shown in FIG. 13A, the writing transistor 31 is disposed on a top left side in the figure, the storage capacitor 33 is disposed on a right-hand side of the writing transistor 31, and the drive transistor 32 is disposed on the right-hand side of the storage capacitor 33.

As shown in FIG. 13A, the gate 31g of the writing transistor 31 is formed as a part of the first metallic layer M1. The drain 31d and the source 31s of the writing transistor 31 are formed as parts of the second metallic layer M2, respectively. In this case, however, the parts of the second metallic layer M2 are formed so as to be independent of each other in the second metallic layer M2. It is noted that the part of the second metallic layer M2 forming the drain 31d of the writing transistor 31 will be referred hereinafter to as “the second metallic layer M2 on the drain 31d side,” and the part of the second metallic layer M2 forming the source 31s of the writing transistor 31 will be referred hereinafter to as “the second metallic layer M2 on the source 31s side.”

The second metallic layer M2 on the drain 31d side is formed so as to have a rectangular shape. Also, the second metallic layer M2 on the source 31s side is formed so as to have an L-like shape. In this case, the second metallic layer M2 on the drain 31d side, and the second metallic layer M2 on the source 31s side are disposed on a part of the first metallic layer M1 forming the gate 31g of the writing transistor 31 so that each of long sides of the rectangle, and a long segment portion of the L-like shape are approximately parallel with each other.

Moreover, in the substrate shown in FIG. 13A, that is, in the existing substrate, the second metallic layer M2 on the drain 31d side, and the second metallic layer M2 on the source 31s side are formed so that each of the long sides of the rectangle, and the long segment portion of the L-like shape have approximately the same length.

FIG. 14 is a timing chart explaining the operation of the pixel 101 realized on the substrate shown in FIG. 13A, that is, the existing pixel 101. In this timing chart shown in FIG. 14, a range from the time t₄ to the time t₈ of the timing chart shown in FIG. 3 is enlarged.

From the comparison of the flow chart shown in FIG. 14 with the flow chart shown in FIG. 3, it is found out that the following phenomenon occurs. That is to say, in the case of the existing pixel 101, when the bootstrap operation is carried out at the first of the emission time period T₆ at and after the time t₈, as indicated by a circular frame 51 shown in FIG. 14, the gate potential Vg of the drive transistor 32 drops. In other words, at the time t₈ as the end time point of the write+mobility correction time period T₅, the potential of the scanning line WSL10 is switched from the high potential over to the low potential, that is, the potential of the scanning line WSL10 largely changes by ΔWS. At this time, there occurs a phenomenon that the gate voltage Vg of the driving transistor 32 drops owing to a so-called feedthrough effect.

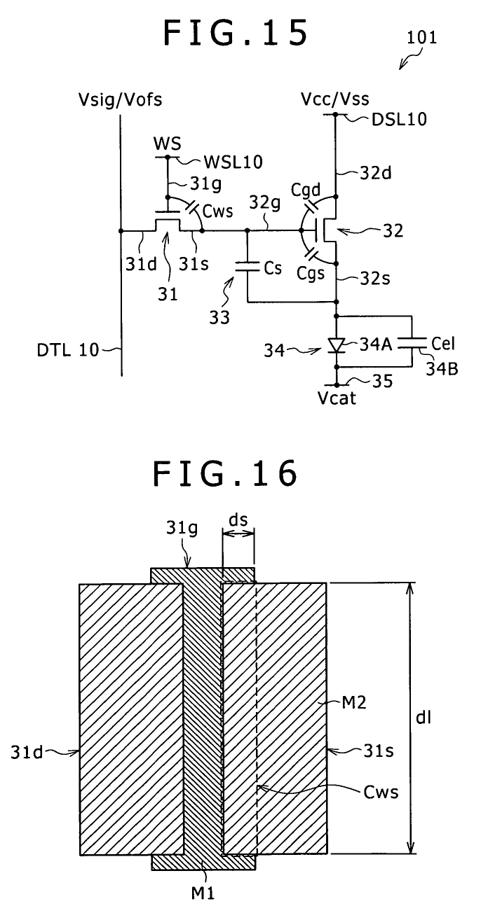

An equivalent circuit of the pixel 101 at the time point indicated by the circular frame 51 shown in FIG. 14 is as shown in FIG. 15. In addition, an amount, Vfs, of gate voltage Vg dropped of the driving transistor 32 owing to the feedthrough effect (hereinafter referred to as “a feedthrough voltage drop amount”) at this time point is expressed by Expression (3):

$$Vfs = \frac{Cws \times Δ WS}{[ \{ \frac{Cel \cdot ( Cs + Cgs )}{( Cel + Cs + Cgs )} \} + Cws + Cgd ]} \qquad ( 3 )$$

where Cws is a parasitic capacitance between the source 31s and the gate 31g of the writing transistor 31 (hereinafter referred to as “a writing transistor parasitic capacitance”), Cel is a parasitic capacitance of the storage capacitor 34B in the light emitting element 34 (hereinafter referred to as “an organic EL capacitance”), Cs is a capacitance of the storage capacitance 33, Cgs is a parasitic capacitance between the gate 32g and the source 32s of the driving transistor 32 (hereinafter referred to as “a driving transistor gate-to-source parasitic capacitance”), and Cgd is a parasitic capacitance between the gate 32g and the drain 32d of the driving transistor 32 (hereinafter referred to as “a driving transistor gate-to-drain parasitic capacitance”).

As shown in a right-hand side member of Expression (3), it is understood that a parameter most influenced by the feedthrough voltage drop amount is one of a denominator, that is, the writing transistor parasitic capacitance Cws.

As shown in FIG. 16, the writing transistor parasitic capacitance Cws changes depending on an area of a portion (overlapping portion), existing above the first metallic layer M1 forming the gate electrode 31g of the writing transistor 31, of the second metallic layer M2 on the source 31s side. That is to say, the writing transistor parasitic capacitance Cws becomes large as the area of the overlapping portion is larger.

Here, a line width d1 of each of the long sides of the overlapping portion, that is, the rectangle-shaped portion in the writing transistor 31 is approximately identical to that in the writing transistor 31 in each of the pixels 101-(1, 1) to 101-(N, M) composing the EL panel. On the other hand, a line width ds of each of short sides disperses in the pixels 101-(1, 1) to 101-(N, M) composing the EL panel. The reason for this dispersion is because the exposure processing described above for any one of the pixels 101-(1, 1) to 101-(N, M) composing the EL panel is carried out independently of the exposure processing for other pixels. That is to say, since the first metallic layer M1 and the second metallic layer M2 are formed for each of the pixels 101-(1, 1) to 101-(N, M) composing the EL panel, it is impossible to perfectly suppress the dispersion of differences ds in short sides between the first metallic layers M1 and the second metallic layers M2 (hereinafter referred to as “line width differences ds”).

That is to say, the line width difference ds disperses in the pixels 101-(1, 1) to 101-(N, M) composing the EL panel. That is to say, an area of a portion, overlapping the first metallic layer M1 forming the gate 31g, of the second metallic layer M2 on the source 31s disperses in the pixels 101-(1, 1) to 101-(N, M) composing the EL panel. Thus, the writing transistor parasitic capacitance Cws disperses in the pixels 101-(1, 1) to 101-(N, M) composing the EL panel. As a result, as apparent from Expression (3), the feedthrough voltage drop amount Vfs disperses in the pixels 101-(1, 1) to 101-(N, M) composing the EL panel.

Moreover, when the feedthrough voltage drop amount Vfs disperses in the pixels 101-(1, 1) to 101-(N, M) composing the EL panel, the luminance disperses in the pixels 101-(1, 1) to 101-(N, M) composing the EL panel accordingly. In this case, when a difference in luminance between one pixel and any of the pixels adjacent thereto is 1% or more, there is caused the problem that a user who sees the entire EL panel as one image visually recognizes this luminance difference as non-uniformity. That is to say, there is caused the problem described in the opening of the paragraph of “SUMMARY OF THE INVENTION.”

In other words, the primary factor causing the problem described in the opening of the paragraph of “SUMMARY OF THE INVENTION” is that the writing transistor parasitic capacitance Cws disperses in the pixels 101-(1, 1) to 101-(N, M) composing the EL panel.

In order to solve the problem as described above, the inventor of the embodiment of the present invention has arrived at a technical idea that the area of the second metallic layer M2 on the source 31s side of the writing transistor 31 is made small as compared with the case of the related art, more properly, a technical idea that the area of the portion, overlapping the first metallic layer M1 forming the gate 31g of the writing transistor 31, of the second metallic layer M2 on the source 31s side of the writing transistor 31 is made small as compared with the case of the related art.

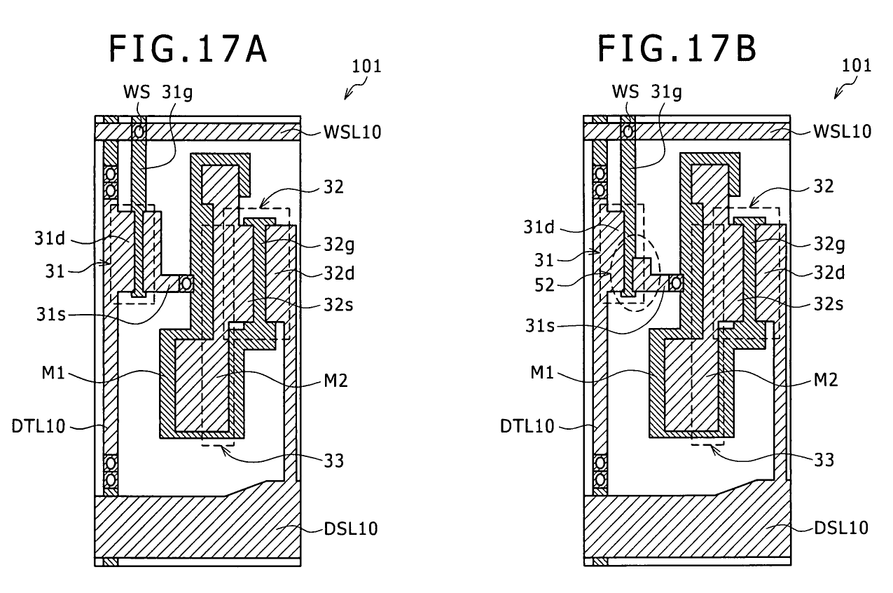

The inventor of the embodiment of the present invention has invented a layout shown in FIG. 17B as a layout of a substrate of a pixel circuit 101 based on the technical idea described above.

That is to say, FIG. 17B is a top plan view showing a layout of the substrate of the pixel circuit 101 (electronic circuit) according to an embodiment of the present invention. Hereinafter, the substrate made based on the layout shown in FIG. 17B will be referred to as “the substrate of the embodiment of the present invention shown in FIG. 17B.”

In order to clarify the feature of the substrate of the embodiment of the present invention shown in FIG. 17B, the existing layout of the substrate of the pixel circuit 101 is shown in FIG. 17A. That is to say, FIG. 17A is identical to FIG. 13A. However, illustration magnification of FIG. 17A is slightly different from that of FIG. 13A. The substrate made based on the layout shown in FIG. 17A will be referred hereinafter to as “the existing substrate shown in FIG. 17A.”

From comparison of the substrate of the embodiment of the present invention shown in FIG. 17B with the existing substrate shown in FIG. 17A, the constituent elements on the substrate, and the disposition positions of these constituent elements in the substrate of the embodiment of the present invention shown in FIG. 17B are basically identical to those in the existing substrate shown in FIG. 17A. However, as shown within a circular dotted line frame 52 of FIG. 17B, it is understood that the area of the second metallic layer M2 on the source 31s of the writing transistor 31 is smaller in the substrate of the embodiment of the present invention shown in FIG. 17B than in the existing substrate shown in FIG. 17A.

In this case, any of the writing transistor parasitic capacitances Cws in the pixel 101-(1, 1) to 101-(N, M) composing the EL panel is smaller in the substrate of the embodiment of the present invention shown in FIG. 17B than in the existing substrate shown in FIG. 17A. As a result, as apparent from Expression (3), any of the feedthrough voltage drop amounts in the pixel 101-(1, 1) to 101-(N, M) composing the EL panel is smaller in the substrate of the embodiment of the present invention shown in FIG. 17B than in the existing substrate shown in FIG. 17A.

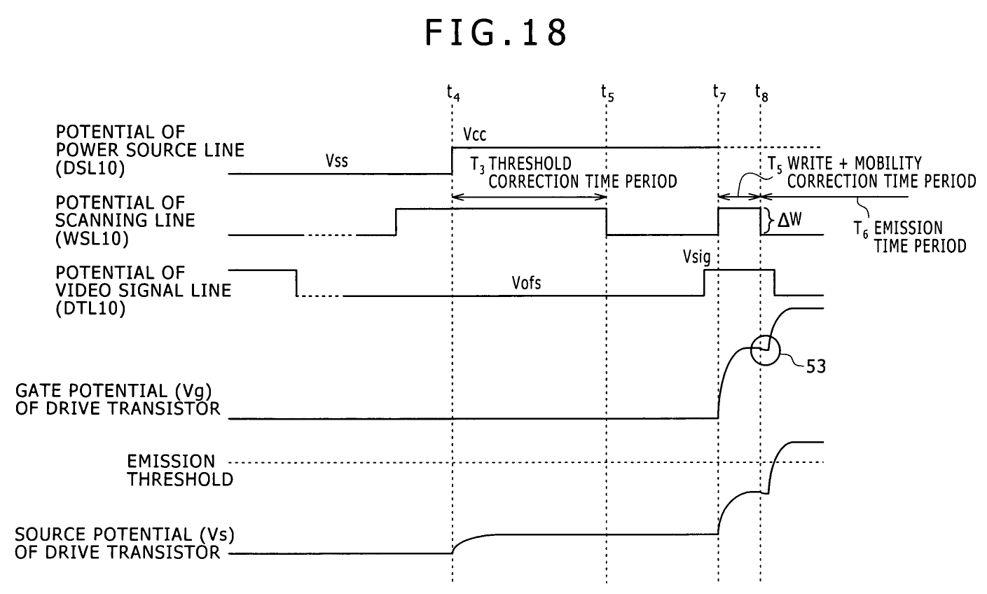

FIG. 18 is a timing chart explaining an operation of the pixel 101 realized on the substrate of the embodiment of the present invention shown in FIG. 17B, that is, an operation of the pixel circuit 101 according to the embodiment of the present invention. In FIG. 18, the range from the time t₄ to the time t₈ of the timing chart shown in FIG. 3 is enlarged.

From comparison of a circular frame 53 shown in FIG. 18 with the circular frame 51 in FIG. 14 explaining the operation of the existing pixel circuit 101, it is understood that the amount of gate potential Vg dropped of the drive transistor 32, that is, the feedthrough voltage drop amount is smaller in the pixel circuit 101 of the embodiment of the present invention (refer to FIG. 18) than in the existing pixel circuit 101 (refer to FIG. 14).

Here, the fact that any of the writing transistor parasitic capacitances Cws in the pixel 101-(1, 1) to 101-(N, M) composing the EL panel is smaller in the substrate of the embodiment of the present invention shown in FIG. 17B than in the existing substrate shown in FIG. 17A means the following matter. That is to say, that fact means that the degree of the dispersion of the writing transistor parasitic capacitances Cws in the pixel circuits 101-(1, 1) to 101-(N, M) composing the EL panel is smaller in the substrate of the embodiment of the present invention shown in FIG. 17B than in the existing substrate shown in FIG. 17A.

From this, the fact that the degree of the dispersion of the writing transistor parasitic capacitances Cws in the pixel circuits 101-(1, 1) to 101-(N, M) composing the EL panel becomes small results in that the feedthrough voltage drop amounts in the pixel circuits 101-(1, 1) to 101-(N, M) composing the EL panel leads to a decrease in degree of the dispersion. As a result, the degree of the dispersion of the luminances in the pixel circuits 101-(1, 1) to 101-(N, M) composing the EL panel also decreases.

Here, when the degree of the dispersion of the luminances can be reduced so that a difference in luminance between one pixel and any of the pixels adjacent thereto is made smaller than 1%, the user who sees the entire EL panel as one image can visually recognize the image having no non-uniformity occurring therein. That is to say, it is possible to solve the problem described in the opening in the paragraph of “SUMMARY OF THE INVENTION.”

In other words, in order to solve the problem described in the opening in the paragraph of “SUMMARY OF THE INVENTION,” all that is required is that the area of the portion, overlapping the first metallic layer M1 forming the gate 31g of the writing transistor 31, of the second metallic layer M2 on the source 31s side is made smaller than the predetermined area allowing the difference in luminance between one pixel and any of the pixels adjacent thereto to be made about 1%.

Here, with regard to a technique for reducing the area of the overlapping portion, there are expected a technique for making the line width difference ds (refer to FIG. 16) smaller than existing one, and a technique for making the line width d1 of each of the long sides (refer to FIG. 16) shorter than existing one. Although any of these techniques may be adopted, in the embodiment of the present invention, the latter technique is adopted.

Next, an EL panel according to an embodiment of the present invention will be described.

The EL panel includes the pixel circuit (pixel) 101 having the light emitting element 34, having the diode characteristics, for emitting a light in accordance with the drive current, the writing transistor 31 for sampling the video signal, the driving transistor 32 for supplying the drive current to the light emitting element 34, and the storage capacitor 33 for holding therein the predetermined potential. The storage capacitor 33 is connected to each of the anode side of the light emitting element 34, and the gate of the driving transistor 32. In this case, in the pixel circuit 101, the laminated portion of the first metallic layer M1 serving as the gate of the writing transistor 31, and the second metallic layer M2 serving as the source of the writing transistor 31 is formed so as to have the area equal to or smaller than the predetermined area.

In addition, preferably, in the second metallic layer M2, a first portion serving as the drain of the writing transistor 31 is formed apart from a second portion serving as the source of the writing transistor 31, and the second portion is formed in a way that the length of the line thereof facing the first portion becomes equal to or smaller than the given value.

The embodiments of the present invention are by no means limited to the embodiments described above, and thus various changes can be made without departing the gist of the present invention.

The present application contains subject matter related to that disclosed in Japanese Priority Patent Application JP 2008-142438 filed in the Japan Patent Office on May 30, 2008, the entire content of which is hereby incorporated by reference.

It should be understood by those skilled in the art that various modifications, combinations, sub-combinations and alterations may occur depending on design requirements and other factor in so far as they are within the scope of the appended claims or the equivalents thereof.

What is claimed is:

1. An electronic circuit, comprising:
a light emitting element, having diode characteristics, for emitting a light in accordance with a drive current;
a sampling transistor for sampling a video signal;
a driving transistor for supplying the drive current to said light emitting element; and
a hold capacitor for holding therein a predetermined potential, said hold capacitor being connected to each of an anode side of said light emitting element, and a gate of said driving transistor;
wherein a laminated portion of a first metallic layer serving as a gate of said sampling transistor, and a second metallic layer serving as a source of said sampling transistor is formed so as to have an area equal to or smaller than a predetermined area.

2. The electronic circuit according to claim 1, wherein in said second metallic layer, a first portion serving as a drain of said sampling transistor is formed apart from a second portion serving as said source of said sampling transistor; and
said second portion is formed in a way that a length of a line thereof facing said first portion becomes equal to or smaller than a given value.

3. A panel, comprising
a pixel circuit having:
a light emitting element, having diode characteristics, for emitting a light in accordance with a drive current;
a sampling transistor for sampling a video signal;
a driving transistor for supplying the drive current to said light emitting element; and
a hold capacitor for holding therein a predetermined potential, said hold capacitor being connected to each of an anode side of said light emitting element, and a gate of said driving transistor;
wherein in said pixel circuit, a laminated portion of a first metallic layer serving as a gate of said sampling transistor, and a second metallic layer serving as a source of said sampling transistor is formed so as to have an area equal to or smaller than a predetermined area.

4. The panel according to claim 3, wherein in said second metallic layer, a first portion serving as a drain of said sampling transistor is formed apart from a second portion serving as said source of said sampling transistor; and
said second portion is formed in a way that a length of a line thereof facing said first portion becomes equal to or smaller than a given value.
